(19) United States
(12) Patent Application Publication
(10) Pub. No.: US 2014/0084258 A1
(43) Pub. Date: Mar. 27, 2014

(54) ORGANIC LIGHT EMITTING DISPLAY DEVICE

(71) Applicant: SAMSUNG DISPLAY CO., LTD., Yongin-city (KR)

(72) Inventor: Jung Mi Choi, Seoul (KR)

(73) Assignee: Samsung Display Co., Ltd., Yongin-city (KR)

(21) Appl. No.: 13/754,507

(22) Filed: Jan. 30, 2013

(30) Foreign Application Priority Data
Sep. 27, 2012 (KR) 10-2012-0108105

(51) Int. Cl. H01L 51/52; H01L 33/08

(52) U.S. Cl. CPC H01L 51/5203; H01L 33/08
USPC 257/40; 257/88

(57) ABSTRACT

An organic light emitting display device is disclosed. In one aspect, the device includes a display panel including a display area including a plurality of pixels displaying an image and a non-display area formed in a peripheral area of the display area while including a plurality of non-pixels. The display panel also includes a substrate in which the pixels and the non-pixels are formed and a pixel defining layer including a plurality of openings corresponding to the pixels and the non-pixels, the pixel defining layer being formed on the substrate. The device further includes organic light emitting devices which are formed in the openings corresponding to the pixels and generate a light in response to corresponding drive voltages and organic layers formed in the openings corresponding to the non-pixels. The organic layers do not receive the drive voltages.

### CROSS-REFERENCE TO RELATED APPLICATIONS

This U.S. non-provisional patent application claims priority under 35 U.S.C. §119 of Korean Patent Application No. 10-2012-0108105, filed on Sep. 27, 2012, the entire contents of which are hereby incorporated by reference.

### BACKGROUND

1. Field

The described technology generally relates to organic light emitting devices, and more particularly, to an organic light emitting device that can reduce a bright deviation.

2. Description of the Related Technology

There have been developed various types of display devices such as a liquid crystal display (LCD) device, an organic light emitting display (OLED) device, a plasma display panel (PDP) device and an electrophoretic display device (EPD).

An organic light emitting display device displays an image using an organic light emitting diode generating a light by recombination of an electron and a hole. The organic light emitting display device has advantages of high response speed and low power consumption.

An organic light emitting display device generally includes an organic light emitting device including an anode, an organic light emitting layer, and a cathode. A hole and an electron are injected into the organic emitting layer through an anode and a cathode, and are recombined in the organic emitting layer to generate an exciton. The exciton emits energy discharged when an excited state returns to a ground state as light. An organic light emitting layer may be formed by an inkjet printing method or a nozzle printing method.

### SUMMARY

One inventive aspect is to reduce a brightness deviation of an organic light emitting display device.

Another aspect is an organic light emitting display device. The organic light emitting display may include a display panel including a display area including a plurality of pixels displaying an image and a non-display area formed in a peripheral area of the display area while including a plurality of non-pixels. The display panel comprises a substrate in which the pixels and the non-pixels are formed; a pixel defining layer including a plurality of openings corresponding to the pixels and the non-pixels, the pixel defining layer being formed on the substrate; organic light emitting devices which are formed in the openings corresponding to the pixels and generate a light in response to corresponding drive voltages; and organic layers formed in the openings corresponding to the non-pixels. The organic layers do not receive the drive voltages.

### BRIEF DESCRIPTION OF THE DRAWINGS

FIG. 1 is a top plan view of an organic light emitting display device in accordance with one embodiment.

FIG. 2 is a cross sectional view of a pixel of a display area illustrated in FIG. 1.

FIG. 3 is a cross sectional view of a non-pixel of a non-display area illustrated in FIG. 1.

FIG. 4A is a drawing an atmospheric state of upper portions of pixels when non-pixels are not formed on a non-display area.

FIG. 4B is a drawing an atmospheric state of upper portions of pixels and non-pixels when non-pixels are formed on a non-display area.

FIGS. 5A through 5D are drawings various embodiments of non-pixels illustrated in FIG. 1.

### DETAILED DESCRIPTION

Embodiments of inventive concepts will be described more fully hereinafter with reference to the accompanying drawings. This inventive concept may, however, be embodied in many different forms and should not be construed as limited to the embodiments set forth herein. In the drawings, the size and relative sizes of layers and regions may be exaggerated for clarity. Like numbers refer to like elements throughout.

In the drawings, the thickness of layers and regions may be exaggerated for clarity. It will also be understood that when an element such as a layer, region or substrate is referred to as being “on” or “onto” another element, it may lie directly on the other element or intervening elements or layers may also be present. Like reference numerals refer to like elements throughout the specification.

Spatially relatively terms, such as “beneath,” “below,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

Embodiments of the inventive concept may be described with reference to cross-sectional illustrations. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

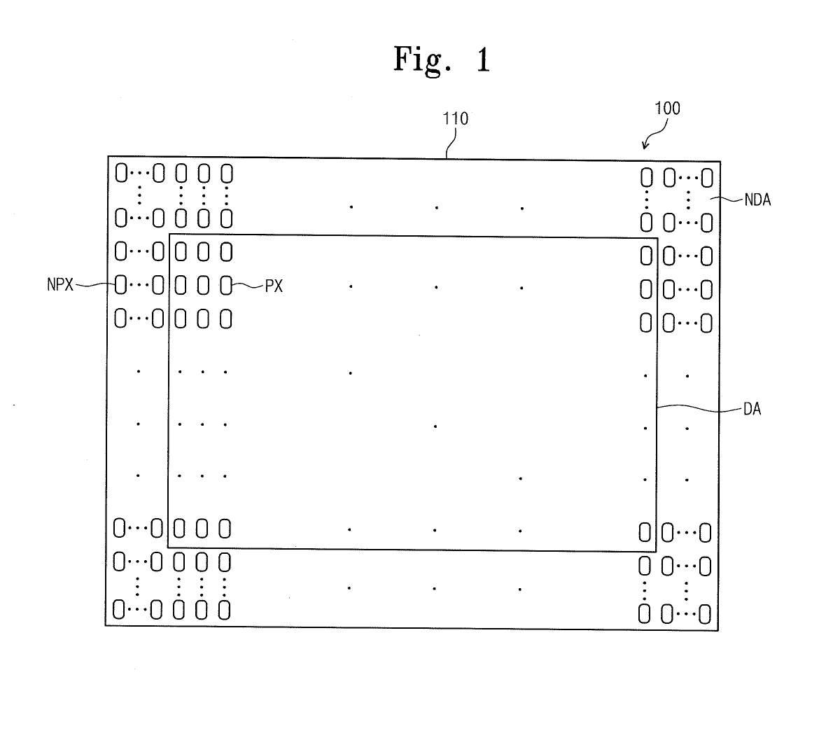

FIG. 1 is a top plan view of an organic light emitting display device in accordance with some embodiments of the inventive concept.

Referring to FIG. 1, the organic light emitting display device 100 includes a display panel 110. The display panel 110 may include a display area DA displaying an image and a non-display area NDA formed in a peripheral area of the display area DA while not displaying an image.

The display area DA of the display panel 110 generates a light to display an image and includes a plurality of pixels PX arranged in a matrix form. The pixels PX includes organic light emitting devices. To display an image, the organic light emitting devices receive corresponding drive voltages to generate a light. Each of the organic light emitting devices includes a first electrode, an organic light emitting layer formed on the first electrode, and a second electrode formed on the organic light emitting layer.

The non-display area NDA includes a plurality of non-pixels NPX. The non-pixels NPX may be disposed around the display area DA. The non-pixels NPX include organic layers. In one embodiment, the organic layers do not receive drive voltages. Thus, the non-pixels NPX may not operate and the organic layers of the non-pixels NPX may not generate a light.

The pixels PX and the non-pixels NPX may be defined by a pixel defining layer. The pixel defining layer is formed at an interface between the pixels PX and the non-pixels NPX to include a plurality of openings corresponding to the pixels PX and the non-pixels NPX. Areas in which the pixels PX and the non-pixels NPX are formed may be defined by the openings of the pixel defining layer. Organic light emitting devices are formed in the openings corresponding to the pixels PX and organic layers are formed in the openings corresponding to the non-pixels NPX.

Organic light emitting layers of the pixels PX and the organic layers of the non-pixels NPX may be concurrently formed of the same material and by the same method. As an example, the organic light emitting layers of the pixels PX and the organic layers of the non-pixels NPX may be concurrently formed by an inkjet printing method.

In one embodiment, the openings are filled with ink by the inkjet printing method and a solvent is evaporated and thereby the organic light emitting layers and the organic layers may be formed. Due to evaporation of a solvent, an atmospheric environment of upper portions of the pixels PX and the non-pixels NPX may become different. As an area in which an ink is evaporated becomes greater, the density of solvent in the atmosphere becomes high. As an area in which an ink is evaporated becomes smaller, the density of solvent in the atmosphere becomes low. The density of solvent in the atmosphere may be saturated.

As the density of solvent in the atmosphere becomes high, the number of solvent particles being evaporated from an ink to the atmosphere may be reduced. Thus, a drying speed of the ink may slow. As the density of solvent in the atmosphere becomes low, the number of solvent particles being evaporated from an ink to the atmosphere may be increased. Thus, a drying speed of the ink may be increased.

When non-pixels NPX are not formed in the non-display area NDA, since a solvent particle being evaporated from the non-display area NDA does not exist, a drying speed of the ink filling the opening of the pixel PX of the interface of the display area DA becomes fast. As approaching the center of the display area DA from the interface of the display area DA, the density of solvent in the atmosphere may become high and may be saturated in a predetermined area. In an area in which the density of solvent in the atmosphere is saturated, drying speeds of the ink may be substantially the same. However, in an area in which the density of solvent in the atmosphere is not saturated, drying speeds of the ink may be different. The higher a drying speed of the ink is, the smaller a thickness of the organic light emitting layer is. The slower a drying speed of the ink is, the thicker a thickness of the organic light emitting layer is.

A drying deviation between the ink at the interface of the display area DA and the ink at an area in which a solvent density is saturated in the display area DA may be the highest. Due to the drying deviation, thicknesses of the organic light emitting layers may be formed to be different from each other. Due to a thickness deviation of the organic light emitting layers, a brightness deviation may occur.

In the present embodiment, non-pixels NPX are formed in the non-display area NDA. Organic layers formed of the same organic material as the organic light emitting layer are formed in openings corresponding to the non-pixels NPX. As approaching an interface of the display area DA from the non-display area NDA, the density of solvent becomes high. That is, as approaching an interface of the display area DA from the non-display area NDA, a drying speed of the ink forming the organic layers is slowed. As described above, the density of solvent in the atmosphere may become high then may be saturated. The density of solvent in the atmosphere of an upper portion of the pixel may be saturated at an interface of the display area DA. The density of solvent in the atmosphere becomes high by an ink filling openings corresponding to the non-pixels NPA formed in the non-display area NDA, and then the density of solvent in the atmosphere of an upper portion of the pixel may be saturated at an interface of the display area DA.

The number of non-pixels NPX is set to the number that the density of solvent in the atmosphere of an upper portion of the pixel at an interface of the display area DA can be saturated. The density of solvent in the atmosphere of upper portion of the pixels PX of the display area DA may be saturated by the inks filling openings corresponding to the non-pixels NPX. The density of solvent in the atmosphere of upper portions of the pixels PX of the display area DA can become uniform. In the case that the density of solvent in the atmosphere of upper portion of the pixels PX of the display area DA becomes uniform, a drying deviation of the inks filling openings PX of the display area DA may be reduced. Thus, a thickness deviation of the organic light emitting layers may be reduced and a brightness deviation of pixels PX may be reduced.

Consequently, the organic light emitting display device 100 can reduce a brightness deviation.

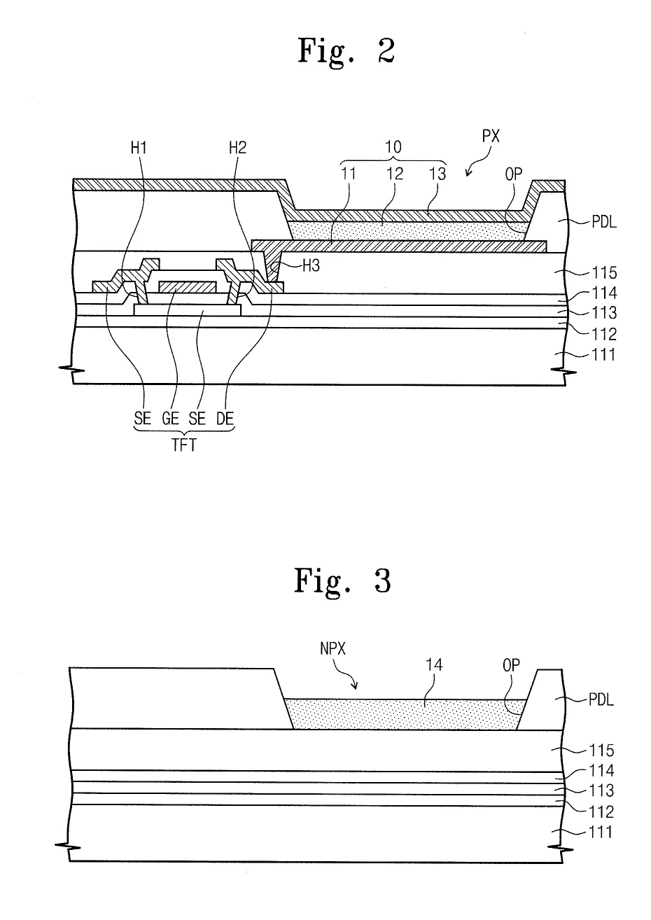

FIG. 2 is a cross sectional view of a pixel of a display area illustrated in FIG. 1.

Although a cross section of an arbitrary pixel is illustrated in FIG. 2, pixels illustrated in FIG. 1 have substantially the same structure.

Referring to FIG. 2, a thin film transistor TFT and an organic light emitting device 10 of a pixel PX driven by the thin film transistor TFT are formed on a substrate 111 of the display panel.

A buffer layer 112 is formed on the substrate 111. A semiconductor layer SM of the thin film transistor TFT is formed on the buffer layer 112. The semiconductor layer SM may be formed of semiconductor of inorganic substance such as amorphous silicon or poly silicon, or organic semiconductor. Although not illustrated in the drawing, the semiconductor layer SM may include a source area, a drain area and a channel area between the drain area and the source area.

A gate insulating layer 113 is formed to cover the semiconductor layer SM. A gate electrode GE of the thin film transistor TFT overlapping the semiconductor layer SM is formed on the gate insulating layer 113. The gate electrode GE may be formed to overlap the channel area of the semiconductor layer SM. The gate electrode GE is connected to a gate line (not shown) applying an on/off signal to the thin film transistor TFT.

An interlayer insulating layer 114 is formed to cover the gate electrode GE. A source electrode SE and a drain electrode DE of the thin film transistor TFT are formed to be spaced apart from each other on the interlayer insulating layer 114. The source electrode SE can be connected to the semiconductor layer SM through a first contact hole H1 formed by penetrating the gate insulating layer 113 and the interlayer insulating layer 114. The source electrode SE is connected to the source area of the semiconductor layer SM. The drain electrode DE can be connected to the semiconductor layer SM through a second contact hole H2 formed by penetrating the gate insulating layer 113 and the interlayer insulating layer 114. The drain electrode DE is connected to the drain area of the semiconductor layer SM.

A protection layer 115 is formed to cover the source electrode SE and the drain electrode DE of the thin film transistor TFT. A top surface of the protection layer 115 may be formed to be flat.

A first electrode 11 corresponding to a pixel PX is formed on the protection layer 115. The first electrode 111 can be connected to the drain electrode DE of the thin film transistor TFT through a third contact hole H3 formed by penetrating the protection layer 115. The first electrode 11 may be defined as a pixel electrode or an anode electrode.

A pixel defining layer PDL defining pixels PX is formed on the protection layer 115. The pixel defining layer PDL includes an opening OP exposing the first electrode 11 corresponding to a pixel PX. The pixel defining layer PDL may be formed to cover a boundary interface of the first electrode 11 and the opening OP of the pixel defining layer PDL can expose a predetermined area of the first electrode 11. The pixel defining layer PDL may be formed of an organic insulating layer. However, it is not limited thereto and may be formed by sequentially stacking an organic layer and inorganic layer.

An organic light emitting layer 12 is formed on the first electrode 11 in the opening OP of the pixel defining layer PDL and a second electrode 13 is formed on the pixel defining layer PDL and the organic light emitting layer 12. The second electrode 13 may be defined as a common electrode or a cathode electrode.

The first electrode 11 may be formed by a transparent electrode or a reflection type electrode. If the first electrode 11 is formed by a transparent electrode, the first electrode 11 may include ITO, IZO or ZnO, etc. If the first electrode 11 is formed by a reflection type electrode, the first electrode 11 may include a reflection layer formed of Ag, Mg, Al, Pt, Pd, Au, Ni, Nd, Ir, Cr or combinations thereof and a transparent conductive layer formed of ITO, IZO, ZnO, etc.

The second electrode 13 may be formed by a transparent electrode or a reflection type electrode. If the second electrode 13 is formed by a transparent electrode, the second electrode 13 may include a layer formed by depositing Li, Ca, LiF/Ca, LiF/Al, Al, Mg or combinations thereof toward the organic light emitting layer 12 and an auxiliary electrode formed of a transparent conductive material such as ITO, IZO or ZnO, etc. on the layer. If the second electrode 13 is formed by a reflection type electrode, the second electrode 13 may be formed of Ag, Mg, Al, Pt, Pd, Au, Ni, Nd, Ir, Cr, Li, Ca, LiF/Ca, LiF/Al or combinations thereof.

The organic light emitting layer 12 may be formed of a low molecular organic or a high molecular organic. The organic light emitting layer 12 may be formed by a multilayer including a hole injection layer (HIL), a hole transporting layer (HTL), an emission layer (EML), an electron transporting layer (ETL) and an electron injection layer (EIL). As an illustration, a hole injection layer (HIL) is disposed on the first electrode 11, and then a hole transporting layer (HTL), an emission layer (EML), an electron transporting layer (ETL) and an electron injection layer (EIL) may be sequentially formed on the first electrode 11.

In FIG. 1, the organic light emitting layer 12 is formed only in the opening OP of the pixel defining layer PDL but it is not limited thereto. For instance, the hole injection layer (HIL), the hole transporting layer (HTL), an emission layer (EML), the electron transporting layer (ETL), and the electron injection layer (EIL) may be formed in some other areas besides the opening OP and the light emitting layer of the organic light emitting layer 12 may be formed in the opening OP.

The first electrode 11 may be a positive pole which is a hole injection electrode and the second electrode 13 may be a negative pole which is an electron injection electrode. However, it is not limited thereto and the first electrode 11 may become a negative pole and the second electrode 13 may be a positive pole depending on a driving method of the organic light emitting display device 100.

The organic light emitting device 10 includes the first electrode 11, the organic light emitting layer 12 and the second electrode 13. The organic light emitting device 10 may emit a red light, a green light and a blue light according to a current flow to display predetermined image information.

A drive power supply for emitting the organic light emitting layer 12 of the organic light emitting device 10 of a pixel PX is applied to the first electrode 11 by the thin film transistor TFT and a power supply having a pole opposite to the driving power supply is applied to the second electrode 13. In this case, a hole and an electron injected into the organic light emitting layer 12 combine with each other to form an exciton and the organic light emitting device 10 is emitted while the exciton transits to a ground state.

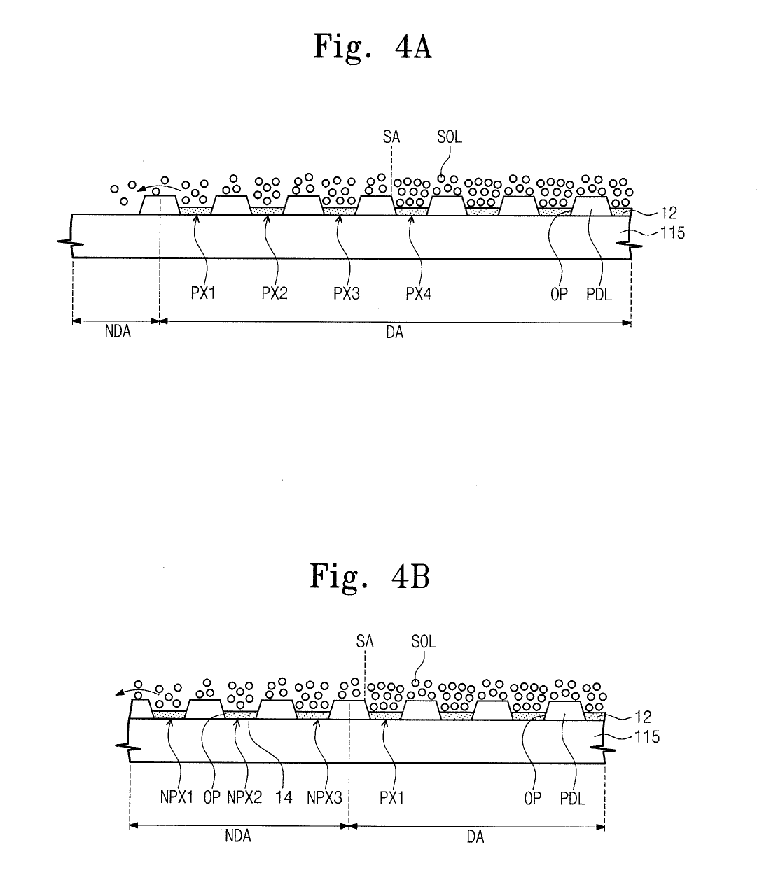

FIG. 3 is a cross sectional view of a non-pixel of a non-display area illustrated in FIG. 1.

Referring to FIG. 3, a non-display pixel NPX is formed on a substrate 111 of a non-display area NDA. A buffer layer 112 may be formed on the substrate 111 and a gate insulating layer 113 may be formed on the buffer layer 112. An interlayer insulating layer 114 may be formed on the gate insulating layer 113 and a protection layer 115 may be formed on the interlayer insulating layer 114.

A pixel defining layer PDL defining non-pixels NPX may be formed on the protection layer 115. The pixel defining layer PDL includes an opening OP corresponding to the non-pixel NPX. An organic layer 14 may be formed on the protection layer 115 in the opening OP corresponding to the non-pixel NPX. The organic layer 14 of the non-pixel NPX may be formed of the same material as the organic light emitting layer 12 of the pixel PX.

The non-pixel NPX does not receive a drive voltage for emitting the organic layer 14. Thus, the non-pixel NPX is not driven.

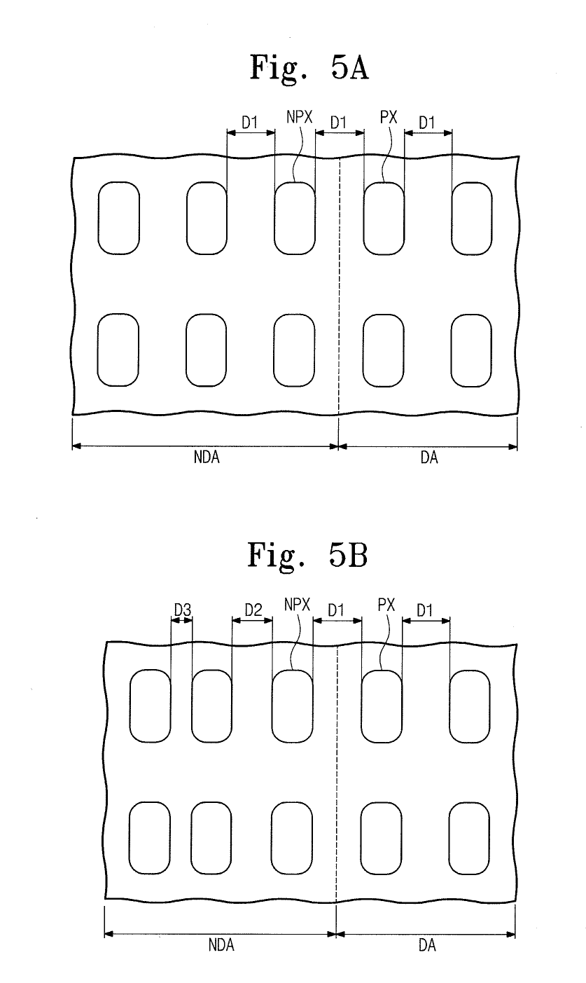

FIG. 4A is a drawing an atmospheric state of upper portions of pixels when non-pixels are not formed on a non-display area.

In FIG. 4A, an atmospheric state of upper portions of pixels of an arbitrary row is illustrated as an illustration. For convenience of description, in FIG. 4A, only the protection layer 115, the pixel defining layer PDL, the organic light emitting layer 12 and solvent particles SOL evaporated from an ink forming the organic light emitting layer 12 are illustrated.

Referring to FIG. 4A, since an organic layer is not formed on the non-display area NDA, a solvent particle SOL being evaporated form the non-display area NDA does not exist. Solvent particles SOL being evaporated from an ink filling an opening OP of a first pixel PX1 adjacent to an interface of the display area DA may move to an adjacent non-display area NDA. In this case, the density of solvent in the atmosphere of an upper portion of the first pixel PX1 becomes low and the number of solvent particles SOL being evaporated from the ink may be increased. Thus, a drying speed of the ink filling the opening OP of the first pixel PX1 adjacent to the interface of the display area DA may become fast.

The density of solvent in the atmosphere of an upper portion of the first pixel PX1 is a state that is not saturated. Solvent particles SOL being evaporated from an ink filling an opening OP of a second pixel PX2 adjacent to the first pixel PX1 may move to the first pixel PX1. However, since the evaporated solvent particles SOL exist in an atmosphere of an upper portion of the first pixel PX1, solvent particles less than the number of the solvent particles SOL moving from the atmosphere of the upper portion of the first pixel PX1 to the adjacent non-display area NDA may move from an atmosphere of an upper portion of the second pixel PX2 to the atmosphere of the upper portion of the first pixel PX1. In this case, the density of solvent in the atmosphere of the upper portion of the second pixel PX2 may be higher than the density of solvent in the atmosphere of the upper portion of the first pixel PX1.

Referring to the atmospheric state, the density of solvent in the atmosphere of an upper portion of a third pixel PX3 may be higher than the density of solvent in the atmosphere of an upper portion of the second pixel PX2. Generally, particles being evaporated may be saturated in an atmosphere. That is, particles being evaporated reach a saturation state that the density of solvent increases, and then does not increase any more.

As approaching the center of the display area DA from an interface of the display area DA, the density of solvent in the atmosphere of upper portions of pixels PX becomes high and may be saturated in a predetermined area. As illustrated in FIG. 4A, the density of solvent may be saturated from an atmospheric area SA of an upper portion of a fourth pixel PX4. Thus, drying speeds of inks in the pixels PX existing from the fourth pixel PX4 to the center of the display area DA may be identical to one another. However, drying speeds of inks in the first through third pixels PX1-PX3 may be different from the drying speeds of inks in the pixels PX existing from the fourth pixel PX4 to the center of the display area DA.

As described above, due to a deviation of drying speeds of inks filling the openings OP, a thickness deviation of the organic light emitting layer may occur. A thickness deviation between the organic light emitting layer 12 of the first pixel PX1 and the organic light emitting layers 12 of pixels PX existing from the fourth pixel PX4 to the center of the display area DA may be greatest. If a thickness deviation of the organic light emitting layers 12 is great, a brightness deviation may occur.

FIG. 4B is a drawing an atmospheric state of upper portions of pixels and non-pixels when non-pixels are formed on a non-display area.

In FIG. 4B, an atmospheric state of upper portions of pixels and non-pixels of an arbitrary row is illustrated as an illustration. For convenience of description, in FIG. 4B, only the protection layer 115, the pixel defining layer PDL, the organic light emitting layer 12, the organic layer 14 and solvent particles SOL evaporated from an ink forming the organic light emitting layer 12 and the organic layer 14 are illustrated.

Referring to FIG. 4B, the organic light emitting layers 12 of the pixels PX and the organic layers 14 of the non-pixels NPX may be concurrently formed of the same material and by the same method. As an illustration, the organic light emitting layers 12 of the pixels PX and the organic layers 14 of the non-pixels NPX may be concurrently formed by an inkjet printing method.

Openings OP are filled with an ink by the inkjet printing method, and then solvent is evaporated to form the organic light emitting layers 12 and the organic layers 14.

The non-pixels NPX of the display area NDA include three non-pixels NPX1-NPX3. Solvent particles SOL being evaporated from an ink filling an opening OP of the first non-pixel NPX1 may move to a left area in which non-pixels are not formed. In this case, the density of solvent in an atmosphere of an upper portion of the first non-pixel NPX 1 becomes low and the number of solvent particles SOL may be increased. Thus, a drying speed of the ink filling the opening OP of the first non-pixel NPX 1 may be increased.

The density of solvent in an atmosphere of an upper portion of the first non-pixel NPX1 is a state which is not saturated. Solvent particles SOL being evaporated from an ink filling an opening OP of the second non-pixel NPX2 adjacent to the first non-pixel NPX1 may move to the adjacent first non-pixel NPX1. However, since the evaporated solvent particles SOL exist in an atmosphere of an upper portion of the first non-pixel NPX 1, solvent particles less than the number of the solvent particles SOL moving from the atmosphere of the upper portion of the first non-pixel NPX1 to the left area may move from an atmosphere of an upper portion of the second non-pixel NPX2 to the atmosphere of the upper portion of the first non-pixel NPX1. In this case, the density of solvent in the atmosphere of the upper portion of the second non-pixel NPX2 may be higher than the density of solvent in the atmosphere of the upper portion of the first non-pixel NPX1.

Referring to the atmospheric state, the density of solvent in the atmosphere of an upper portion of a third non-pixel NPX3 may be higher than the density of solvent in the atmosphere of the upper portion of the second non-pixel NPX2. Generally, particles being evaporated may be saturated in an atmosphere. That is, particles being evaporated reach a saturation state that the density of solvent increases, and then does not increase any more. Thus, as approaching an interface of the display area DA from the non-display area NDA, the density of solvent in the atmosphere becomes high.

The number of non-pixels NPX is set to the number that the density of solvent in the atmosphere of an upper portion of the pixel at an interface of the display area DA can be saturated. As an illustration, as illustrated in FIG. 4B, the density of solvent in the atmosphere of upper portions of the three non-pixels NPX1-NPX3 increases, and then the density of solvent may be saturated from an atmospheric area of the first pixel PX1 disposed at an interface of the display area DA. That is, the density of solvent in the atmosphere of upper portions of pixels PX of the display area DA may be saturated by inks filling the openings OP corresponding to non-pixels NPX.

Since the density of solvent in the atmosphere of upper portions of the pixels PX of the display area DA is saturated, the density of solvent in the atmosphere of upper portions of pixels PX of the display area DA can become uniform. In the case that the density of solvent in the atmosphere of upper portions of the pixels PX of the display area DA becomes uniform, a drying deviation of the inks filling openings PX of the display area DA may be reduced. Thus, a thickness deviation of the organic light emitting layers 12 may be reduced and a brightness deviation of the pixels PX may be reduced.

Consequently, the organic light emitting display device 100 in accordance with some embodiments of the inventive concept can reduce a brightness deviation.

Although the non-pixels NPX of the non-display area NDA include the three non-pixels NPX1-NPX3 as an illustration, the number of the non-pixels NPX is not limited thereto. In the case that the non-pixels NPX are not used, as a size of the display panel 110 becomes large, a deviation between the density of solvent in the atmosphere of an upper portion of pixel PX that exists at an interface of the display panel 110 and the density of solvent in the atmosphere of an upper portion of pixel PX that exists at the center of the display panel 110 may become great. Thus, as a size of the display panel 110 becomes large, the number of non-pixels NPX used to saturate the density of solvent in the atmosphere of upper portions of pixels PX of the display area DA may be increased.

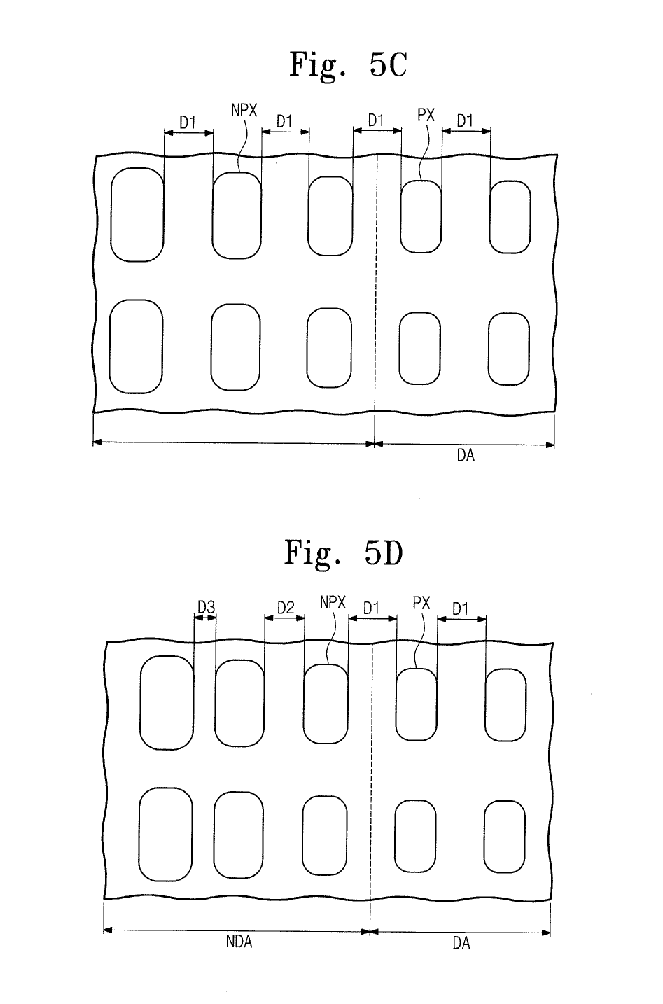

FIGS. 5A through 5D are drawings various embodiments of non-pixels illustrated in FIG. 1. For convenience of description, in FIGS. 5A through 5D, six non-pixels and four pixels arranged in two rows and five columns are illustrated. However, the number of the non-pixels and the pixels is not limited thereto and the number of the non-pixels may be the same as the number of the pixels.

Referring to FIGS. 5A through 5D, if the non-pixels NPX can saturate the density of solvent in the atmosphere of upper portions of the pixels PX of the display area DA, the non-pixels NPX can be formed in various forms.

For example, as illustrated in FIG. 5A, sizes of the non-pixels NPX may be substantially the same as sizes of the pixels PX. Also, distances D1 between the non-pixels NPX may be substantially the same as first distances D1 between the pixels PX.

As illustrated in FIG. 5B, sizes of the non-pixels NPX may be substantially the same as sizes of the pixels PX. A second distance D2 and a third distance D3 between the non-pixels NPX may be smaller than the first distance D1 between the pixels PX. The second and third distances D2 and D3 of the non-pixels NPX may be smaller with the distance from an interface of the display area DA. For instance, the third distance D3 may be smaller than the second distance D2.

As illustrated in FIG. 5C, sizes of the non-pixels NPX may be larger than sizes of the pixels PX. Distances D1 between the non-pixels NPX may be substantially the same as first distances D1 between the pixels PX.

As illustrated in FIG. 5D, sizes of the non-pixels NPX may be larger than sizes of the pixels PX and the sizes of the non-pixels NPX may be larger with the distance from an interface of the display area DA. A second distance D2 and a third distance D3 between the non-pixels NPX may be smaller than the first distance D1 between the pixels PX. The second and third distances D2 and D3 of the non-pixels NPX may be smaller with the distance from an interface of the display area DA. For instance, the third distance D3 may be smaller than the second distance D2.

At least one of the disclosed embodiments can reduce a brightness deviation of an organic light emitting display device.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents. Therefore, the above-disclosed subject matter is to be considered illustrative, and not restrictive.

What is claimed is:

1. An organic light emitting display device comprising:
a display panel comprising a display area and a non-display area, wherein the display comprises a plurality of pixels configured to display an image, and wherein the non-display area is formed in a peripheral area of the display area and comprises a plurality of non-pixels,
wherein the display panel further comprises:
a substrate in which the pixels and the non-pixels are formed;
a pixel defining layer including a plurality of openings corresponding to the pixels and the non-pixels, wherein the pixel defining layer is formed on the substrate;
a plurality of organic light emitting devices formed in the openings corresponding to the pixels and configured to generate a light in response to corresponding drive voltages; and
a plurality of organic layers formed in the openings corresponding to the non-pixels,
wherein the organic layers do not receive the drive voltages.

2. The organic light emitting display device of claim 1, wherein the non-display area further comprises a protection layer formed on the substrate, wherein the pixel defining layer is formed on the protection layer, and wherein the organic layers are formed on the protection layer in the openings corresponding to the non-pixels.

3. The organic light emitting display device of claim 1, wherein the display area further comprises:
a plurality of thin film transistors configured to apply the corresponding drive voltages to the organic light emitting devices of the pixels, respectively, wherein the thin film transistors are formed on the substrate; and
a protection layer formed on the substrate to cover the thin film transistor.

4. The organic light emitting display device of claim 3, wherein each of the thin film transistors is electrically connected to the respective organic light emitting device through a contact hole.

5. The organic light emitting display device of claim 4, wherein each of the organic light emitting devices comprises:
a first electrode electrically connected to the thin film transistor through the contact hole;
an organic light emitting layer formed on the first electrode; and
a second electrode formed on the organic light emitting layer,
wherein a predetermined area of the first electrode is exposed by the opening and wherein the organic light emitting layer is formed on the first electrode in the opening.

6. The organic light emitting display device of claim 5, wherein the organic layers and the organic light emitting layers are formed of the same material.

7. The organic light emitting display device of claim 1, wherein the pixel defining layer is formed of an organic insulating layer.

8. The organic light emitting display device of claim 1, wherein the pixel defining layer is formed to have a multilayer structure of an inorganic insulating layer and an organic insulating layer.

9. The organic light emitting display device of claim 1, wherein the sizes of the non-pixels are substantially the same as the sizes of the pixels and wherein the distances between the non-pixels are substantially the same as the distances between the pixels.

10. The organic light emitting display device of claim 1, wherein the sizes of the non-pixels are substantially the same as the sizes of the pixels, wherein distances between the non-pixels are less than the distances between the pixels, and wherein the distances between the non-pixels become less as the non-pixels are located farther from an interface of the display area.

11. The organic light emitting display device of claim 1, wherein the sizes of the non-pixels are greater than the sizes of the pixels and wherein the distances between the non-pixels are substantially the same as the distances between the pixels.

12. The organic light emitting display device of claim 1, wherein the sizes of the non-pixels are greater than the sizes of the pixels, wherein the sizes of the non-pixels are greater than the distance from an interface of the display area, wherein the distances between the non-pixels are less than the distances between the pixels, and wherein the distances between the non-pixels become less as the non-pixels are located farther from an interface of the display area.
